(19) United States
(12) Patent Application Publication
(10) Pub. No.: US 2026/0040788 A1
(43) Pub. Date: Feb. 5, 2026

(54) DISPLAY DEVICE AND AN ELECTRONIC DEVICE INCLUDING THE SAME

(71) Applicant: Samsung Display Co., Ltd., Yongin-si (KR)

(72) Inventors: Changkyu Jin, Yongin-si (KR); Minki Yang, Yongin-si (KR); Daehyun Kim, Yongin-si (KR); Heyjin Shin, Yongin-si (KR); Hyunae Park, Yongin-si (KR); Hyojoon Song, Yongin-si (KR)

(21) Appl. No.: 19/282,487

(22) Filed: Jul. 28, 2025

(30) Foreign Application Priority Data
Aug. 1, 2024 (KR) 10-2024-0102709

(51) Int. Cl. H10K 59/131; H10K 59/65

(52) U.S. Cl. CPC H10K 59/1315; H10K 59/65

(57) ABSTRACT

A display device includes a substrate including a first display area and a second display area including a sensor area, a first data line arranged in the second display area and extending in a first direction, a second data line arranged in the second display area, extending in the first direction, and arranged apart from the first data line in a second direction crossing the first direction, and a third data line arranged between the first data line and the second data line, and including a first portion protruding from the first data line in the second direction and a second portion connected to the first portion and extending in the first direction, wherein an area between the first data line and the second data line includes a wiring area and the sensor area, and wherein the third data line is arranged in the wiring area.

### CROSS-REFERENCE TO RELATED APPLICATION

The present application claims priority to and the benefit of Korean Patent Application No. 10-2024-0102709, filed on Aug. 1, 2024, in the Korean Intellectual Property Office, the entire disclosure of which is incorporated herein by reference.

### BACKGROUND

### 1. Field

Aspects of some embodiments relate to a display device.

### 2. Description of the Related Art

A display device visually displays data. The display device may provide images using light-emitting diodes. Display devices are becoming more diverse in their uses, and various designs have been attempted to improve the quality of display devices.

The above information disclosed in this Background section is only for enhancement of understanding of the background of the invention and therefore it may contain information that does not form.

### SUMMARY

Aspects of some embodiments are directed to a display device.

Additional aspects will be set forth in part in the description which follows and, in part, will be apparent from the description, or may be learned by practice of the presented embodiments of the disclosure.

According to some embodiments of the present disclosure, there is provided a display device including: a substrate including a first display area and a second display area including a sensor area; a first data line arranged in the second display area and extending in a first direction; a second data line arranged in the second display area, extending in the first direction, and arranged apart from the first data line in a second direction crossing the first direction; and a third data line arranged between the first data line and the second data line, and including a first portion protruding from the first data line in the second direction and a second portion connected to the first portion and extending in the first direction, wherein an area between the first data line and the second data line includes a wiring area and the sensor area, and wherein the third data line is arranged in the wiring area.

In some embodiments, the sensor area overlaps an opening in a pixel definition layer and an opening in a light blocking layer.

In some embodiments, the display device further includes: a fourth data line arranged between the first data line and the second data line and including a third portion protruding in the second direction from the second data line and a fourth portion connected to the third portion and extending in the first direction.

In some embodiments, the fourth data line is arranged in the wiring area.

In some embodiments, a distance by which the first data line adjacent to the sensor area and the second data line are arranged apart in the second direction is longer than a distance by which the first data line adjacent to the wiring area and the second data line are arranged apart in the second direction.

In some embodiments, the third data line and the fourth data line are not in the sensor area.

In some embodiments, a component is on a lower part of the substrate in the sensor area.

In some embodiments, the component is a light sensor.

In some embodiments, the component is an infrared sensor.

According to some embodiments of the present disclosure, there is provided a display device including: a substrate including a first display area and a second display area including a sensor area; a first data line arranged in the second display area and extending in a first direction; a second data line arranged in the second display area, extending in the first direction, and arranged apart in a second direction crossing the first direction; and a common voltage line arranged between the first data line and the second data line, wherein an area between the first data line and the second data line includes a wiring area and the sensor area, and wherein the common voltage line is arranged in the wiring area.

In some embodiments, the common voltage line includes a first common voltage line and a second common voltage line extending in the first direction and arranged spaced apart in the second direction, and a third common voltage line and a fourth common voltage line extending in the second direction and arranged apart in the first direction.

In some embodiments, the first common voltage line, the second common voltage line, the third common voltage line, and the fourth common voltage line are connected to each other.

In some embodiments, the first common voltage line, the second common voltage line, the third common voltage line, and the fourth common voltage line each have a rectangular shape.

In some embodiments, the common voltage line is electrically connected to a counter electrode of an organic light-emitting diode on the common voltage line to which a common voltage is applied through a contact hole

According to some embodiments of the present disclosure, there is provided a display device including: a substrate including a first display area and a second display area including a sensor area; a first driving voltage line arranged in the second display area and extending in a first direction; a second driving voltage line arranged apart from the first driving voltage line in a second direction crossing the first direction and extending in the first direction; a first data line arranged between the first driving voltage line and the second driving voltage line and extending in the first direction; a second data line arranged between the first data line and the second driving voltage line and extending in the first direction; and a third driving voltage line including a fifth portion protruding in the second direction from the first driving voltage line and a sixth portion connected to the fifth portion and extending in the first direction, wherein an area between the first data line and the second data line includes a general area and the sensor area, and wherein a distance by which the first data line adjacent to the sensor area and the second data line are arranged apart in the second direction is longer than a distance by which the first data line adjacent to the general area and the second data line are arranged apart in the second direction.

In some embodiments, the third driving voltage line is arranged apart from the sensor area.

In some embodiments, the display device further includes: a fourth driving voltage line including a seventh portion protruding in the second direction from the second driving voltage line and an eighth portion connected to the seventh portion and extending in the first direction.

In some embodiments, the fourth driving voltage line is arranged apart from the sensor area.

In some embodiments, the third driving voltage line and the fourth driving voltage line are not arranged in the sensor area.

In some embodiments, a component is on a lower part of the substrate in the sensor area.

According to some embodiments of the present disclosure, there is provided an electronic device including: a processor configured to provide input image data; and a display device configured to display an image based on the input image data, the display device including: a substrate including a first display area and a second display area including a sensor area; a first data line arranged in the second display area and extending in a first direction; a second data line arranged in the second display area, extending in the first direction, and arranged apart from the first data line in a second direction crossing the first direction; and a third data line arranged between the first data line and the second data line, and including a first portion protruding from the first data line in the second direction and a second portion connected to the first portion and extending in the first direction, wherein an area between the first data line and the second data line includes a wiring area and the sensor area, and wherein the third data line is arranged in the wiring area.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic plan views of a display device according to some embodiments of the present disclosure;

FIGS. 3A and 3B are schematic cross-sectional views of the display device according to some embodiments of the present disclosure;

FIG. 4 is a schematic equivalent circuit diagram of one pixel circuit provided in the display device according to some embodiments of the present disclosure;

FIG. 5 is a schematic plan view of a portion of a display area in the display device according to some other embodiments of the present disclosure;

FIG. 6 is a cross-sectional view taken along the line I-I′ of the display device of FIG. 5 according to some embodiments of the present disclosure;

FIG. 7 is a cross-sectional view taken along the line II-II′ of the display device of FIG. 5 according to some embodiments of the present disclosure; and

FIGS. 8 to 10 are schematic plan views of a second display area according to some embodiments of the present disclosure.

### DETAILED DESCRIPTION

As the disclosure allows for various suitable changes and numerous embodiments, particular embodiments will be illustrated in the drawings and described in detail in the written description. The attached drawings for illustrating some embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, the present invention will be described in detail by explaining some embodiments of the invention with reference to the attached drawings. Like reference numerals in the drawings denote like elements, and thus their descriptions may not be repeated.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted 1 accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

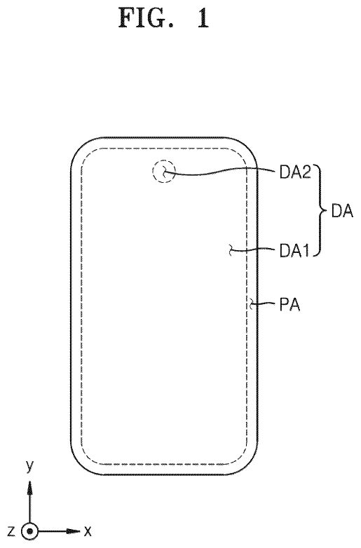

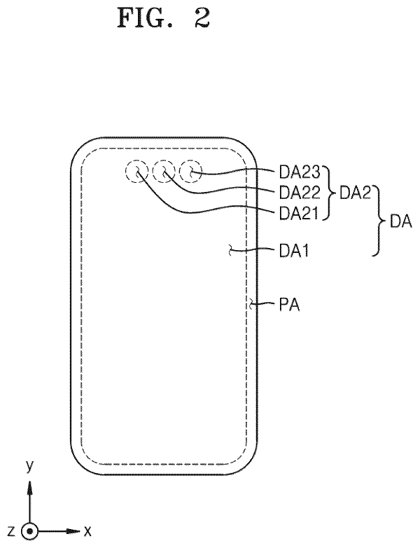

FIG. 1 and FIG. 2 are schematic plan views of a display device according to some embodiments of the present disclosure.

The display device according to some embodiments may be an electronic device such as a smartphone, a mobile phone, a navigation device, a game console, a TV, a vehicle head unit, a notebook computer, a laptop computer, a tablet computer, a personal media player (PMP), or a personal digital assistant (PDA). Additionally, the electronic device may be a flexible device.

A display device 1 may include a display area DA and a peripheral area PA outside the display area DA. In a plan view, the display area DA may have a rectangular or substantially rectangular shape as shown in FIG. 1. According to some other embodiments, the display area DA may have a polygonal shape such as a triangle, a pentagon, a hexagon, a circular shape, an oval shape, an irregular shape, etc. The display area DA may have rounded corners at its edges. The peripheral area PA may be a type of non-display area where no display elements are placed. The display area DA may be entirely surrounded by the peripheral area PA.

A plurality of pixels P including various display elements such as organic light-emitting diodes OLEDs may be arranged in the display area DA. The plurality of pixels P include multiple pixels PX that may be arranged in various suitable forms such as a stripe arrangement, a pentile arrangement, and a mosaic arrangement along the x and y directions to implement (e.g., display) an image.

The display area DA may include a first display area DA1 and a second display area DA2. At least a portion of the display area DA may be set as the second display area DA2. As illustrated in FIG. 1, only a portion of the display area DA may be set as the second display area DA2. According to some other embodiments, the entire display area DA may be set as the second display area DA2.

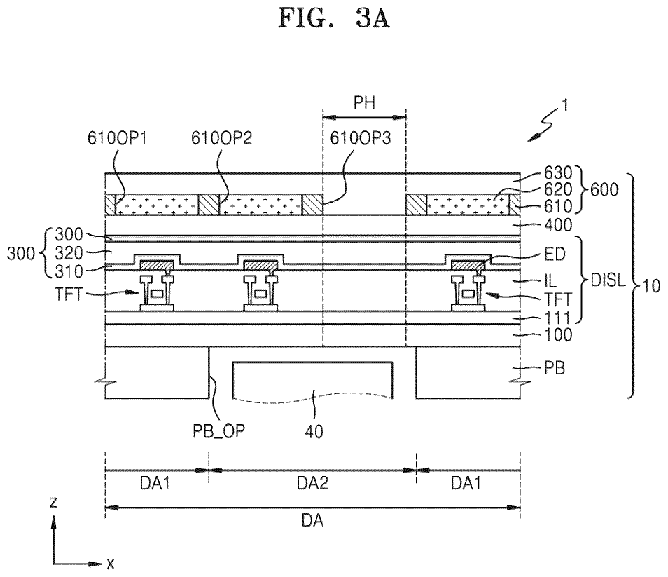

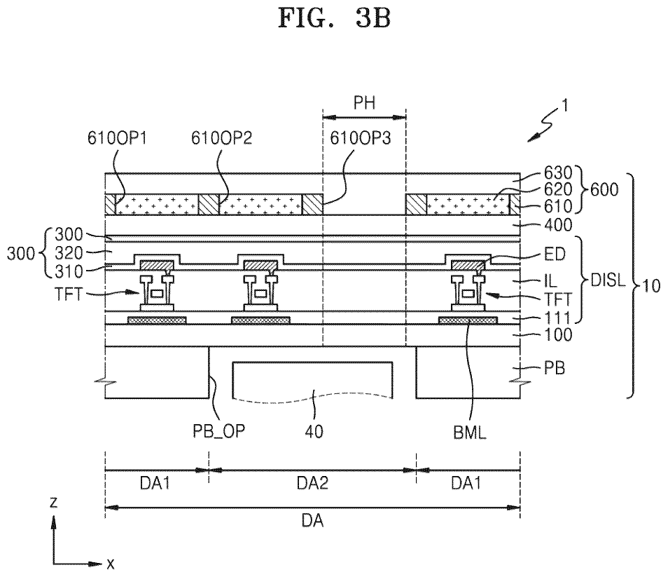

The second display area DA2 is an area where a component 40 is arranged at the bottom of the display panel corresponding to the second display area DA2, as described below with reference to FIGS. 3a and 3b, and may correspond to a component area. The component 40 may be a camera, a light sensor, a proximity sensor, an iris sensor, etc.

FIG. 1 illustrates that one second display area DA2 is positioned within a display area DA. According to some other embodiments, as illustrated in FIG. 2, the display device 1 may include two or more second display areas DA2, and shapes and sizes of the plurality of second display areas DA2 may be different from each other.

When viewed from a direction approximately perpendicular to an upper surface of the display device 1, the shape of the second display area DA2 may have various suitable shapes, such as a circle, an oval, a polygon such as a square, a star shape, or a diamond shape. Components 40 with different functions may be placed corresponding to each of the plurality of second display areas DA2. According to some embodiments, a camera may be placed in a 2nd-1 display area DA21, a light sensor may be placed in a 2nd-2 display area DA22, and a proximity sensor may be placed in a 2nd-3 display area DA23.

In some examples, an electronic device includes a processor (e.g., a graphic processing unit (GPU) or the like), which is configured to provide input image data, and a display device, which is configured to display an image based on the input image data. The display device is further described below. The input image data may include red image data, green image data, and blue image data. In some embodiments, the input image data may further include white image data. As another example, the input image data may include magenta image data, yellow image data, and cyan image data.

FIGS. 3A and 3B are cross-sectional views schematically illustrating a portion of a cross-section of the display device 1 according to some embodiments of the present disclosure.

Referring to FIG. 3A, the display device 1 may include a display panel 10 and a component 40 arranged to overlap the display panel 10.

The display panel 10 may include the display area DA, and the display area DA may include the first display area DA1 that occupies most of the display area DA, and the second display area DA2 that has a relatively small area compared to the first display area DA1.

The display panel 10 may include a substrate 100, a display layer DISL on the substrate 100, a touch screen layer 400, an anti-reflection layer 600, and a lower protective film PB disposed under the substrate 100. A window that protects the display panel 10 may be further placed on an upper portion of the display panel 10.

The substrate 100 may include glass or polymer resin. A substrate 100 including a polymer resin may have flexible, foldable, rollable, or bendable properties. The substrate 100 may have a multilayer structure including a layer including the aforementioned polymer resin and a layer including an inorganic layer.

The display layer DISL may include a pixel circuit including a thin film transistor TFT, a light emitting element ED that is a display element, and a thin film encapsulation layer 300. The light emitting diode ED may be electrically connected to the thin film transistor TFT disposed underneath. In this regard, FIG. 3A illustrates that a buffer layer 111 is disposed on the substrate 100 and the thin film transistor TFT is disposed on the buffer layer 111. The thin film transistor TFT and the emitting element ED electrically connected to the thin film transistor TFT may be arranged in the first display area DA1 and the second display area DA2, respectively.

In the second display area DA2, a plurality of hole areas PH may be located where no display elements and no wiring constituting pixel circuits are arranged. The hole area PH may be an area through which light/signal emitted from a component 40 arranged corresponding to the second display area DA2 or light/signal incident on the component 40 is transmitted.

As illustrated in FIG. 3B, a blocking metal layer BML may be further disposed in the second display area DA2. The blocking metal layer BML may be placed between the substrate 100 and the buffer layer 111 to prevent or substantially reduce the likelihood of a function of a thin film transistor TFT placed in the second display area DA2 from being deteriorated by light passing through the second display area DA2. The blocking metal layer BML may also be arranged in the first display area DA1. The blocking metal layer BML disposed in the second display area DA2 may include an opening overlapping the hole area PH.

The thin film encapsulation layer 300 may include at least one inorganic encapsulation layer and at least one organic encapsulation layer. According to some embodiments, the thin film encapsulation layer 300 may include first and second inorganic encapsulation layers 310 and 330, and an organic encapsulation layer 320 therebetween.

The touch screen layer 400 may be formed on the thin film encapsulation layer 300. The touch screen layer 400 may obtain coordinate information according to an external input, for example, a touch event of an object such as a finger or a stylus pen. The touch screen layer 400 may include touch electrodes and wires connected to the touch electrodes. The touch screen layer 400 may detect external input using self-capacitance or mutual capacitance.

The anti-reflection layer 600 may reduce a reflectivity of light (e.g., external light) incident from outside toward the display device 1. The anti-reflection layer 600 may include a light blocking layer 610, color filters 620, and an overcoat layer 630. The light blocking layer 610 may include an opening 610OP1 overlapping the light-emitting element ED of the first display area DA and an opening 610OP2 overlapping the light-emitting element ED of the second display area DA2, and color filters 620 may be arranged in each of the aforementioned openings 610OP1, 610OP2. The light blocking layer 610 may include an opening 610OP3 that does not overlap with the light emitting element ED. The opening 610OP3 is an area corresponding to the hole area PH, and a part of the overcoat layer 184 may be located in the opening 610OP3. That is, the color filter 620 and the light blocking layer 610 may not exist in an area of the anti-reflection layer 600 corresponding to the hole area PH.

The color filter 620 may be arranged in consideration of a color of light emitted from each pixel of the display panel 10. For example, the color filter 620 may have red, green, or blue color depending on the color of light emitted from the light emitting element ED. The overcoat layer 630 may include an organic material such as a resin, and the organic material may be transparent.

The display device including the anti-reflection layer 600 including the color filter 620 and the light blocking layer 610 may significantly reduce a thickness of the display device compared to a display device including a polarizing plate.

The window may be placed on the upper part of the display panel 10, for example, on the anti-reflection layer 600, to protect the display panel 10. The window may be bonded to the anti-reflection layer 600 via an adhesive layer such as an optically transparent adhesive. The window may contain glass or plastic material. The glass material may include ultra-thin glass. The plastic material may include polyethersulfone, polyacrylate, polyether imide, polyethylene naphthalate, polyethylene terephthalate, polyphenylene sulfide, polyarylate, polyimide, polycarbonate, cellulose acetate propionate, and/or the like.

The lower protective film PB may be attached to a lower surface of the substrate 100 and serve to support and protect the substrate 100. The lower protective film PB may have an opening PB_OP corresponding to the second display area DA2. By providing the opening PB_OP in the lower protective film PB, a light transmittance of the second display area DA2 may be improved (e.g., increased). The lower protective film PB may be provided including polyethylene terephthalate (PET), polyimide (PI), and/or the like.

An area of the second display area DA2 may be made larger than an area where the component 40 is placed. Accordingly, the area of the opening PB_OP provided in the lower protective film PB may not match the area of the second display area DA2.

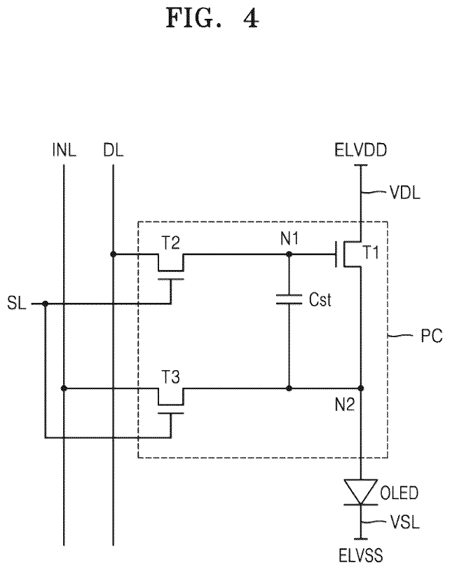

FIG. 4 schematically illustrates an equivalent circuit diagram of a pixel circuit provided in the display device according to some embodiments of the present disclosure.

Referring to FIG. 4, the pixel circuit PC may include a plurality of thin film transistors and at least one capacitor. According to some embodiments, the pixel circuit PC may include a first thin film transistor T1, a second thin film transistor T2, a third thin film transistor T3, and a storage capacitor Cst.

Each of the first thin film transistor T1, the second thin film transistor T2, and the third thin film transistor T3 may be an oxide semiconductor thin film transistor including a semiconductor layer composed of an oxide semiconductor, or a silicon semiconductor thin film transistor including a semiconductor layer composed of polysilicon. Each thin film transistor may have a first electrode and a second electrode and depending on a type of the thin film transistor, the first electrode may be one of a source electrode and a drain electrode, and a second electrode may be the other of the source electrode and the drain electrode. Additionally, each thin film transistor may have a gate electrode.

The first thin film transistor T1 may be a driving thin film transistor. A first electrode of the first thin film transistor T1 may be connected to a driving voltage line VDL that supplies a driving power voltage ELVDD, and a second electrode may be connected to a pixel electrode of an organic light-emitting diode OLED. A gate electrode of the first thin film transistor T1, may be connected to a first node N1. The first thin film transistor T1 may control an amount of current flowing through the organic light emitting diode OLED from the driving power voltage ELVDD in response to a voltage of the first node N1.

The second thin film transistor T2 may be a switching thin film transistor. A first electrode of the second thin film transistor T2 may be connected to a data line DL, and a second electrode may be connected to the first node N1. A gate electrode of the second thin film transistor T2 may be connected to a scan line SL. The second thin film transistor T2 may be turned on (e.g., activated) when a scan signal is supplied to the scan line SL to electrically connect the data line DL and the first node N1.

The third thin film transistor T3 may be an initialization thin film transistor and/or a sensing thin film transistor. A first electrode of the third thin film transistor T3 may be connected to a second node N2, and a second electrode may be connected to an initialization voltage line INL. A gate electrode of the third thin film transistor T3 may be connected to the scan line SL.

The third thin film transistor T3 may be turned on when the scan signal is supplied to the scan line SL to electrically connect the initialization voltage line INL and the second node N2. According to some embodiments, the third thin film transistor T3 may be turned on according to a signal received through the scan line SL to initialize the pixel electrode of the organic light emitting diode OLED with an initialization voltage from the initialization voltage line INL.

According to some embodiments, the third thin film transistor T3 may be turned on when a scan signal is supplied to the scan line SL to sense characteristic information of the organic light emitting diode OLED. The third thin film transistor T3 may have both a function of the initialization thin film transistor and a function of the sensing thin film transistor, or may have only one of the functions. An initialization operation and sensing operation of the third thin film transistor T3 may be performed separately or concurrently (e.g., simultaneously). When the third thin film transistor T3 functions as the sensing thin film transistor, the initialization voltage line INL may be named a sensing line.

The storage capacitor Cst may be connected between the first node N1 and the second node N2. For example, a first capacitor plate of the storage capacitor Cst may be connected to the gate electrode of the first thin film transistor T1, and a second 1 capacitor plate of the storage capacitor Cst may be connected to the pixel electrode of the organic light-emitting diode OLED.

A counter electrode of the organic light-emitting diode OLED may be connected to a common voltage line VSL that provides a common power supply voltage ELVSS.

Although FIG. 4 illustrates that the pixel circuit PC includes three thin film transistors and one storage capacitor, the present invention is not limited thereto. According to some other embodiments, a number of thin film transistors or a number of storage capacitors may vary depending on the design of the pixel circuit PC.

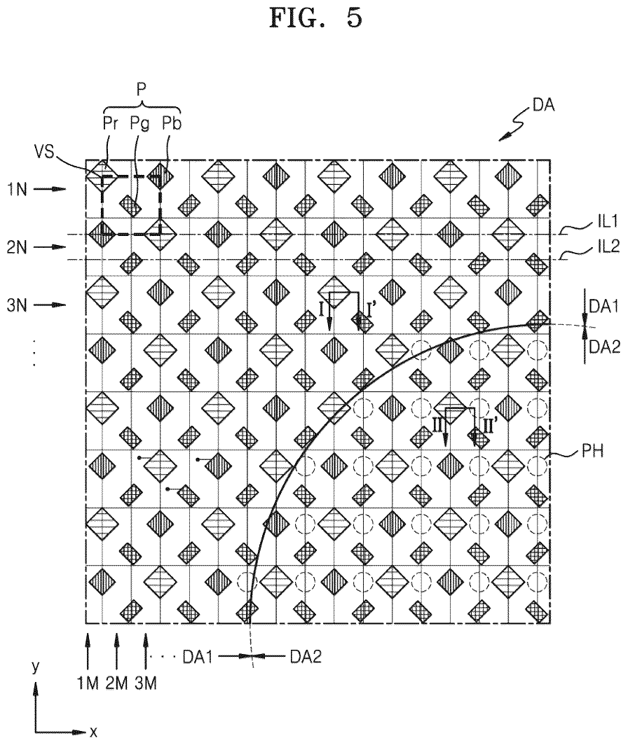

FIG. 5 is a plan view schematically illustrating a portion of the display area of the display device according to some embodiments of the present disclosure.

Referring to FIG. 5, pixels P are arranged in the first display area DA1 and the second display area DA2, and the pixels P may include first to third pixels that emit light of different colors. For convenience of explanation, the first pixel is described as a red pixel Pr, the second pixel is described as a green pixel Pg, and the third pixel is described as a blue pixel Pb.

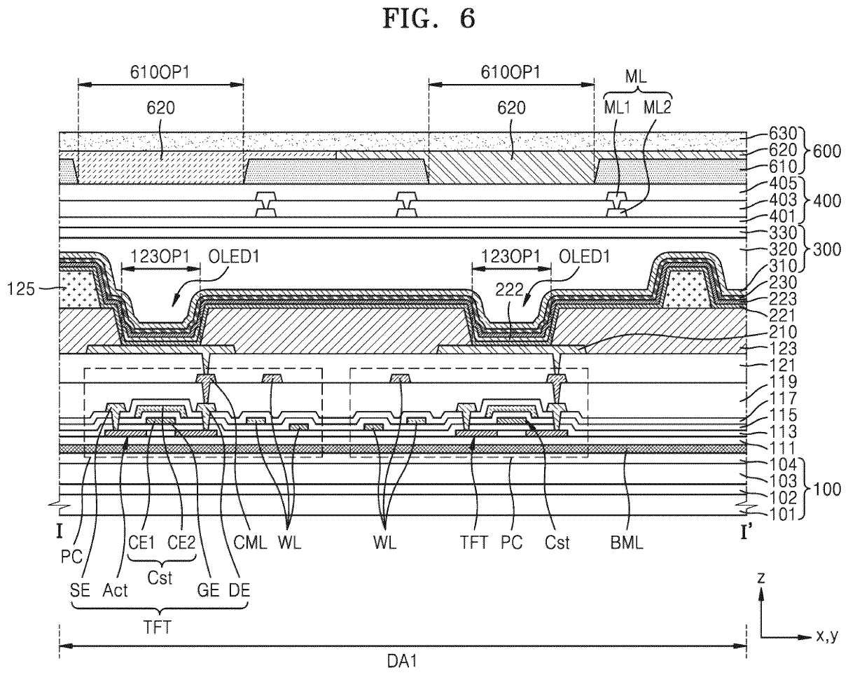

Red pixels Pr, green pixels Pg, and blue pixels Pb may be arranged according to set or predetermined rules in the first display area DA1 and the second display area DA2. Areas demarcated by dashed lines in the display area DA of FIG. 6 are pixel circuit areas where pixel circuits connected to pixels P are arranged.

In each row N, red pixels Pr, green pixels Pg, and blue pixels Pb may be alternately arranged. In each row N, red pixels Pr and blue pixels Pb may be alternately arranged along a first virtual line IL1, and green pixels Pg may be alternately arranged along a second virtual line IL2. This arrangement of pixels may be repeated until the last row. Here, a size (e.g., width or diameter) of the blue pixel Pb and the red pixel Pr may be larger than a size (e.g., width or diameter) of the green pixel Pg.

The red pixels Pr and blue pixels Pb arranged along the first virtual line IL1 and the green pixels Pg arranged along the second virtual line IL2 may be arranged alternately with each other. Accordingly, in a first column 1M, red subpixels Pr and blue subpixels Pb are arranged alternately, in an adjacent second column 2M, green subpixels Pg are arranged at a set or predetermined interval, in an adjacent third column 3M, blue subpixels Pb and red subpixels Pr are arranged alternately, and in an adjacent fourth column 4M, green subpixels Pg are arranged at a set or predetermined interval, and this arrangement of pixels may be repeated up to the last column.

To express this pixel array structure differently, it may be expressed that red pixels Pr are arranged at the first and third vertices facing each other among the vertices of a virtual square VS with the center of the green pixel Pg as the center of the square, and blue pixels Pb are arranged at the second and fourth vertices, which are the remaining vertices. Here, the virtual square VS may be transformed into various suitable shapes such as a rectangle, a rhombus, and a square.

This pixel array structure is called the PenTile™ structure, and by applying a rendering operation that expresses colors by sharing adjacent pixels, high resolution may be implemented with a small number of pixels.

In this specification, the pixel is the smallest unit that implements an image (e.g., emits light) and refers to an area capable of emitting light. When the organic light-emitting diode is used as the display element, the light-emitting area of the pixel may be defined by a light-emitting layer or an opening of a pixel definition layer.

The red pixel Pr, green pixel Pg, and blue pixel Pb illustrated in FIG. 5 may emit red, green, and blue light, respectively, using light-emitting diodes. Therefore, an arrangement of pixels may correspond to an arrangement of light-emitting diodes, which are display elements. For example, a position of the red pixel Pr illustrated in FIG. 5 may indicate a position of the light-emitting diode that emits red light. Similarly, a position of a green pixel Pg may indicate the position of a light-emitting diode that emits green light, and a position of a blue pixel Pb may indicate the position of a light-emitting diode that emits blue light.

A pixel arrangement structures of the first display area DA1 and the second display area DA2 may be the same. Resolutions of the first display area DA1 and the second display area DA2 may be the same. A pixel circuit structure to which the light-emitting diode of the pixel P arranged in the first display area DA1 is connected may be identical to the pixel circuit structure to which the light-emitting diode of the pixel P arranged in the second display area DA2 is connected.

In the second display area DA2, a plurality of hole areas PH may be arranged regularly at regular intervals. The hole region PH is arranged between adjacent pairs of pixels P, that is, between light-emitting diodes, and may not overlap with the light-emitting diodes. According to some embodiments, the hole region PH may be arranged at a boundary of a pair of adjacent pixel circuit regions. The hole region PH may not have the pixel circuit or circuit elements and/or wiring constituting the pixel circuit placed therein. Accordingly, an area occupied by (e.g., the size of) the pixel circuit arranged in the second display area DA2 may be smaller than an area occupied by (e.g., the size of) the pixel circuit arranged in the first display area DA1.

The hole area PH does not mean that an actual hole is formed in the substrate or an insulating layer, but may be defined as an area in which no circuit elements and wiring are arranged and appearing to have a shape similar to a hole when viewed in a direction perpendicular to the upper surface of the substrate 100 (i.e., in a plan view) due to the arrangement of circuit elements forming the pixel circuit on the substrate 100 and wires (e.g., signal lines) connected to the pixel circuit.

Each of the pixels P may be disposed on an upper layer of the corresponding pixel circuit. The pixel P may be disposed directly above the pixel circuit so as to overlap with it, or may be disposed so as to partially overlap with the pixel circuit of another pixel P positioned in an adjacent row or column and offset from the pixel circuit. That is, the pixel P may be placed in the pixel circuit area, or some of the pixels may be placed in another pixel circuit area adjacent to the pixel circuit area. FIG. 5 illustrates an example in which each pixel P is connected to the pixel circuit on the left side of the display device 1.

In FIG. 5, the hole area PH is depicted as being circular, but the present invention is not limited thereto. For example, a shape of the hole region PH may be an ellipse, or a polygon such as a triangle or pentagon. An arrangement and a size of the hole region PH may also vary depending on a structure and an arrangement of the pixel circuit. Also, in FIG. 5, one hole region PH is arranged between a pair of adjacent pixels P, but depending on the structure and the arrangement of the pixel circuit, multiple hole regions PH may be arranged between the pair of adjacent pixels P.

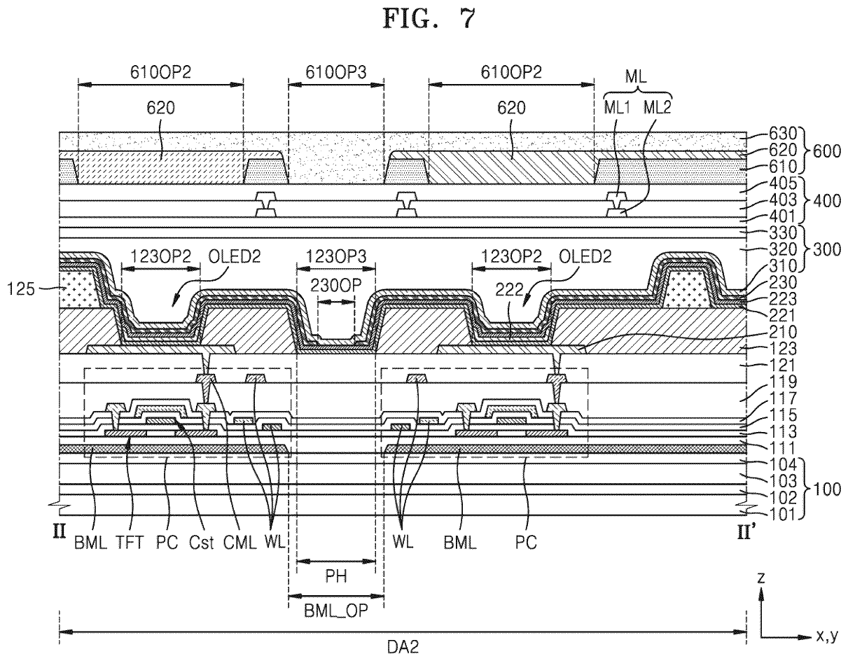

FIG. 6 is a cross-sectional view taken along the line I-I′ of the display device 1 of FIG. 5. FIG. 7 is a cross-sectional view taken along the line II-II′ of the display device of FIG. 5.

FIGS. 6 and 7 illustrate examples in which a light-emitting element, which is the display element of the display panel, includes the organic light-emitting diode. The organic light-emitting diodes may be arranged in the first and second display areas DA1 and DA2, respectively, and for convenience of explanation, the organic light-emitting diode arranged in the first display area DA1 is referred to as a first organic light-emitting diode OLED1, and the organic light-emitting diode arranged in the second display area DA2 is referred to as a second organic light-emitting diode OLED2.

Referring to FIGS. 6 and 7, the first organic light-emitting diode OLED1 and the second organic light-emitting diode OLED2 may be formed on the substrate 100.

The substrate 100 may include a first base layer 101, a first barrier layer 102, a second base layer 103, and a second barrier layer 104. The first base layer 101 and the second base layer 103 may include a polymer resin, and the first barrier layer 102 and the second barrier layer 104 may each include an inorganic insulating material. The polymer resin may include polyethersulfone, polyacrylate, polyether imide, polyethylene naphthalate, polyethylene terephthalate, polyphenylene sulfide, polyarylate, polyimide, polycarbonate, cellulose acetate propionate, and/or the like.

A buffer layer 111 may be disposed on the substrate 100. The buffer layer 111 may reduce or block the penetration of foreign substances, moisture, or external air from a lower portion of the substrate 100. The buffer layer 111 may include an inorganic insulating material such as silicon oxide, silicon oxynitride, silicon nitride, and/or the like, and may be formed as a single layer or multilayer structure including the aforementioned materials.

The blocking metal layer BML may be interposed between the substrate 100 and the buffer layer 111 and may be arranged in the first display area DA1 and the second display area DA2. The blocking metal layer BML may include a conductive metal such as aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like. The blocking metal layer BML may be provided to correspond to a portion of a pixel circuit PC. For example, the blocking metal layer BML may be a structure in which at least regions corresponding to the driving transistors are connected, and may have openings corresponding to remaining circuit elements. According to some other embodiments, the blocking metal layer BML may be provided only in the second display area DA2, or may not be provided in both the first display area DA1 and the second display area DA2.

The first organic light-emitting diode OLED1 and the second organic light-emitting diode OLED2 may each be electrically connected to the pixel circuit PC. The first organic light-emitting diode OLED1 may be electrically connected to a pixel circuit PC between the substrate 100 and the first organic light-emitting diode OLED1, and the second organic light-emitting diode OLED2 may be electrically connected to the pixel circuit PC between the substrate 100 and the second organic light-emitting diode OLED2.

The pixel circuit PC may include the thin film transistor TFT, the storage capacitor Cst, and a plurality of wires WL connected to them. The thin film transistor TFT may include a semiconductor layer Act, a gate electrode GE overlapping a channel region of a semiconductor layer Act, and a source electrode SE and a drain electrode DE respectively connected to a source region and a drain region of the semiconductor layer Act. A first gate insulating layer 113 may be disposed between the semiconductor layer Act and the gate electrode GE, and a second gate insulating layer 115 and a first interlayer insulating layer 117 may be disposed between the gate electrode GE and the source electrode SE, and between the gate electrode GE and the drain electrode DE. A second interlayer insulating layer 119 may be disposed on the source electrode SE and the drain electrode DE.

The semiconductor layer Act may include polysilicon. According to some embodiments, the semiconductor layer Act may include amorphous silicon. According to some embodiments, the semiconductor layer Act may include an oxide semiconductor of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer Act may include the channel region and the source region and the drain region doped with impurities.

The storage capacitor Cst may be disposed overlapping with the thin film transistor TFT. The storage capacitor Cst may include a lower electrode CE1 and an upper electrode CE2 that overlap each other. According to some embodiments, the gate electrode GE of the thin film transistor TFT may include the lower electrode CE1 of the storage capacitor Cst.

The gate electrode GE or the lower electrode CE1 may include a low-resistance conductive material such as molybdenum (Mo), aluminum (Al), copper (Cu), and/or titanium (Ti), and may have a single-layer or multi-layer structure made of the aforementioned materials.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like, and may be a single-layer or multi-layer structure including the above-mentioned materials. The second gate insulating layer 115 may be placed between the lower electrode CE1 and the upper electrode CE2.

The source electrode SE and/or the drain electrode DE may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like, and may be a single-layer or multi-layer structure including the above-mentioned materials. For example, the source electrode SE and/or the drain electrode DE may have a three-layer structure of titanium layer/aluminum layer/titanium layer.

The first gate insulating layer 113, the second gate insulating layer 115, the first interlayer insulating layer 117, and the second interlayer insulating layer 119 may each include an inorganic insulating material such as silicon oxide, silicon oxynitride, or silicon nitride, and may have a single-layer or multi-layer structure including the aforementioned materials.

A planarization layer (also referred to as a flattening layer) 121 may be disposed on the second interlayer insulating layer 119. The planarization layer 121 may include an organic material such as acrylic, BCB (Benzocyclobutene), polyimide, HMDSO (Hexamethyldisiloxane), or the like. In some examples, the planarization layer 121 may include an inorganic material. The planarization layer 121 acts as a protective film covering the first to seventh transistors T1 to T7, and the upper portion of the planarization layer 121 is provided to be planarized. The planarization layer 121 may be provided as a single layer or multiple layers.

The plurality of wires WL may be arranged between the first gate insulating layer 113, the second gate insulating layer 115, the first interlayer insulating layer 117, 1 the second interlayer insulating layer 119, and the planarization layer 121. The plurality of wires WL may include data lines, scan lines, emission control lines, etc. connected to thin film transistors TFTs and capacitors Cst.

A connecting electrode CM may be disposed on the second interlayer insulating layer 119. The thin film transistor TFT may be electrically connected to a first electrode 210 of a corresponding organic light-emitting diode through the connecting electrode CM. The connecting electrode CM may be connected to the thin film transistor TFT through a contact hole of the second interlayer insulating layer 119, and the first electrode 210 may be connected to the connecting electrode CM through a contact hole of the planarization layer 121.

The first organic light-emitting diode OLED1 and the second organic light-emitting diode OLED2 may each include an overlapping structure of the first electrode 210 as a pixel electrode, a light-emitting layer 222, and a second electrode 230 as a counter electrode. The above-described overlapping structure may include a first functional layer 221 between the first electrode 210 and the light-emitting layer 222 and/or a second functional layer 223 between the light-emitting layer 222 and the second electrode 230.

The first electrode 210 may be disposed on the planarization layer (e.g., the flattening layer) 121. The first electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. The first electrode 210 may include a reflective film including the material described above, and a transparent conductive film disposed on or/and below the reflective film. The transparent conductive film may include indium tin oxide (ITO), indium zinc oxide (IZO), zinc oxide (ZnO), indium oxide (In₂O₃ indium oxide), indium gallium oxide (IGO), aluminum zinc oxide (AZO), and/or the like. As an example, the first electrode 210 may have a three-layer structure of ITO layer/Ag layer/ITO layer.

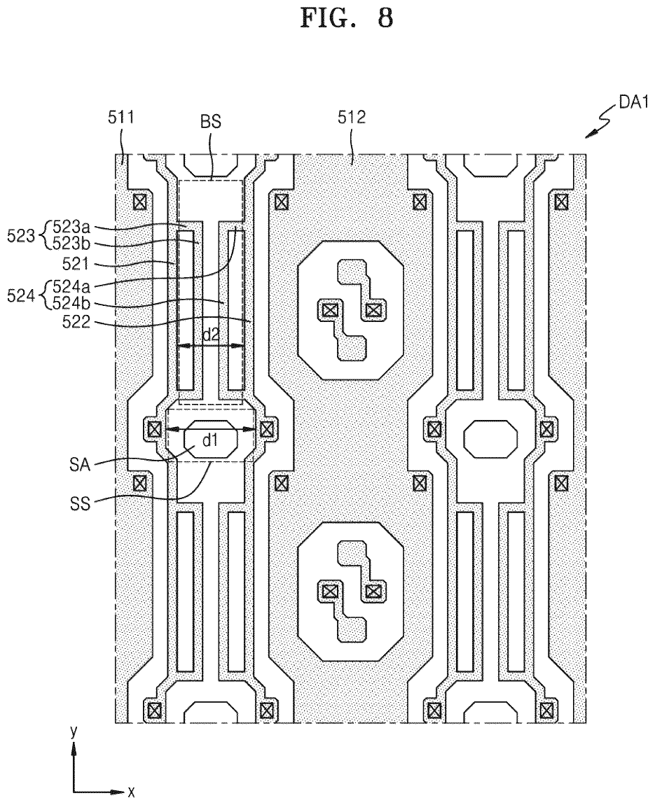

The pixel definition layer 123 covers the edge of the first electrode 210 and may include an opening overlapping the first electrode 210. FIGS. 7 and 8 illustrate an opening (hereinafter referred to as a first opening, 123OP1) overlapping the first electrode 210 of the first organic light-emitting diode OLED1, and an opening (hereinafter referred to as a second opening, 123OP2) overlapping the first electrode 210 of the second organic light-emitting diode OLED2.

The first opening 123OP1 and the second opening 123OP2 of the pixel definition layer 123 may define the light-emitting areas of the first and second organic light-emitting diodes OLED1 and OLED2, respectively. For example, a width of the first opening 123OP1 of the pixel definition layer 123 may correspond to a width of the light-emitting area of the first organic light-emitting diode OLED1, and a width of the second opening 123OP2 of the pixel definition layer 123 may correspond to a width of the light-emitting area of the second organic light-emitting diode OLED2.

The pixel definition layer 123 is a colored, opaque, light-blocking insulating layer, and may have a black color, for example. For example, the pixel definition layer 123 may include a polyimide (PI)-based binder and a pigment mixed with red, green, and blue. In some examples, the pixel definition layer 123 may include a mixture of a cardo-based binder resin and a lactam-based black pigment and a blue pigment. In some examples, the pixel definition layer 123 may include carbon black. The pixel definition layer 123 may prevent or substantially reduce reflection of external light together with the anti-reflection layer 600 described later and improve the contrast of the display panel.

A spacer 125 may be disposed on the pixel definition layer 123. The spacer 125 may include a material different from the pixel definition layer 123. For example, the pixel definition layer 123 may include different materials, such as a negative photosensitive material while the spacer 125 may include a positive photosensitive material, and each may be formed through a separate mask process. The spacer 125 may be a transparent insulating layer.

The light-emitting layer 222 is positioned corresponding to each of the first opening 123OP1 and the second opening 123OP2 of the pixel definition layer 123 and may overlap with the first electrode 210. The light-emitting layer 222 may include a high molecular weight organic material or a low molecular weight organic material that emits light of a set or predetermined color. The first functional layer 221 and the second functional layer 223 may be formed above and below the light-emitting layer 222.

The first functional layer 221 may include a hole transport layer HTL and/or a hole injection layer HIL. The second functional layer 223 may include an electron transport layer ETL and/or an electron injection layer EIL. Unlike the light-emitting layer 222, the first functional layer 221 and/or the second functional layer 223 may be formed entirely on the substrate 100. In other words, the first functional layer 221 and/or the second functional layer 223 may cover the first display area DA1 and the second display area DA2.

The thin film encapsulation layer 300 may cover the first and second organic light-emitting diodes OLED1 and OLED2. According to some embodiments, the thin film encapsulation layer 300 may include the first inorganic encapsulation layer 310, the second inorganic encapsulation layer 330, and the organic encapsulation layer 320 therebetween.

The first and second inorganic sealing layers 310, 330 may each include one or more inorganic insulating materials. The inorganic insulator may include aluminum oxide, titanium oxide, tantalum oxide, hafnium oxide, zinc oxide, silicon oxide, silicon nitride, silicon oxynitride, and/or the like.

The organic encapsulation layer 320 may include a polymer-based material. Polymer-based materials may include acrylic resins, epoxy resins, polyimides, polyethylene, and/or the like. For example, the organic encapsulating layer 320 may include an acrylic resin, such as polymethyl methacrylate, polyacrylic acid, etc. The 1 organic encapsulating layer 320 may be formed by curing a monomer or applying a polymer.

The touch screen layer 400 includes a touch electrode, and the touch electrode may include a conductive layer ML. The touch electrode may include the conductive layer ML having a mesh structure surrounding the light-emitting areas of the first and second organic light-emitting diodes OLED1 and OLED2 on a plane. The conductive layer ML may include a connection structure of a first conductive layer ML1 and a second conductive layer ML2 as illustrated in FIGS. 6 and 7. According to some other embodiments, the conductive layer ML may include one of the first conductive layer ML1 and the second conductive layer ML2. The conductive layer ML may include molybdenum (Mo), mendelevium (Mb), silver (Ag), titanium (Ti), copper (Cu), aluminum (Al), and alloys thereof. The electrode of the touch screen layer 400, for example, the conductive layer ML, may be covered by the light blocking layer 610.

The touch screen layer 400 may include a first touch insulating layer 401 on the thin film encapsulation layer 300, a second touch insulating layer 403 on the first touch insulating layer 401, and a third touch insulating layer 405 on the second touch insulating layer 403. The first conductive layer ML1 may be interposed between the first touch insulating layer 401 and the second touch insulating layer 403, and the second conductive layer ML2 may be interposed between the second touch insulating layer 403 and the third touch insulating layer 405.

The first to third touch insulating layers 401, 403, and 405 may include inorganic insulating materials and/or organic insulating materials. According to some embodiments, the first touch insulating layer 401 and the second touch insulating layer 403 may include an inorganic insulating material, and the third touch insulating layer 405 may include an organic insulating material.

The light blocking layer 610 of the anti-reflection layer 600 may include openings that overlap the light-emitting areas of the first and second organic light-emitting diodes OLED1 and OLED2. FIG. 6 illustrates an opening (hereinafter referred to as a fourth opening, 610OP1) overlapping the first opening 123OP1 of the light-emitting area of the first organic light-emitting diode OLED1 and/or the pixel definition layer 123, and FIG. 7 illustrates an opening (hereinafter referred to as a fifth opening, 610OP2) overlapping the second opening 123OP2 of the light-emitting area of the second organic light-emitting diode OLED2 and/or the pixel definition layer 123.

A width of the fourth opening 610OP1 of the light blocking layer 610 may be equal to or greater than a width of the light-emitting area of the first organic light-emitting diode OLED1 and/or a width of the first opening 123OP1 of the pixel definition layer 123. FIG. 6 illustrates that the width of the fourth opening 610OP1 of the light blocking layer 610 is greater than (e.g., larger than) the width of the first opening 123OP1 of the light-emitting area of the first organic light-emitting diode OLED1 and/or the pixel definition layer 123.

Similarly, a width of the fifth opening 610OP2 of the light blocking layer 610 may be equal to or greater than a width of the light-emitting area of the second organic light-emitting diode OLED2 and/or the second opening 123OP2 of the pixel definition layer 123. FIG. 7 illustrates that the width of the fifth opening 610OP2 of the light blocking layer 610 is greater than (e.g., larger than) the width of the second opening 123OP2 of the light-emitting area of the second organic light-emitting diode OLED2 and/or the pixel definition layer 123.

The color filter 620 may be positioned in each of the fourth opening 610OP1 and fifth opening 610OP2 of the light blocking layer 610. Each color filter 620 may have the same color as the color of light emitted from a light-emitting diode positioned below the corresponding color filter 620. For example, as illustrated in FIG. 6, when one of the first organic light-emitting diodes OLED1 of the first display area DA1 emits green light, the color filter 620 positioned in the fourth opening 610OP1 so as to overlap the first organic light-emitting diode OLED1 described above may include a green color filter. Similarly, when one of the second organic light-emitting diodes OLED2 of the second display area DA2 as illustrated in FIG. 7 emits blue light, the color filter 620 positioned in the fifth opening 610OP2 so as to overlap the second organic light-emitting diode OLED2 described above may include a blue color filter.

The overcoat layer 630 may be placed on the light blocking layer 610 and the color filter 620. The overcoat layer 630 is a light-transmitting layer that does not have a color in the visible light band and can flatten the upper surface of the light blocking layer 610 and an upper surface of the color filter 620. The overcoat layer 630 may include a light-transmitting organic material such as an acrylic resin.

As illustrated in FIG. 7, the hole region PH may be located between two adjacent second organic light-emitting diodes OLED2 among a plurality of second organic light-emitting diodes OLED2 arranged in the second display area DA2. The hole region PH may be a region of a set or predetermined area where no light-blocking elements, such as circuit elements and/or wiring connected thereto, are placed.

In order to form the hole area PH in the second display area DA2 while maintaining the resolution of the second display area DA2 to be the same as the resolution of the first display area DA1, the spacing between pixel circuit elements and/or wirings WL connected thereto in the second display area DA2 may be narrower than the spacing between pixel circuit elements and/or wirings WL connected thereto in the first display area DA1.

The pixel definition layer 123 may include an opening (hereinafter, referred to as a third opening, 123OP3) corresponding to the hole area PH, and the light blocking layer 610 may also include an opening (hereinafter, referred to as a sixth opening, 610OP3) corresponding to the hole area PH. The sixth opening 610OP3 is not provided with the color filter 620, and a part of the overcoat layer 630 may be positioned therein. For example, the overcoat layer 630 may at least partially fill the sixth opening 610OP3 and entirely cover the light blocking layer 610 and the color filters 620. The sixth opening 610OP3 overlaps the third opening 123OP3, but a size (e.g., width or diameter) of the sixth opening 610OP3 may be formed to be larger than a size (e.g., width or diameter) of the third opening 123OP3.

The first and second functional layers 221, 223 may also exist in a portion corresponding to the hole region PH. In some examples, the second electrode 230 including a metal element may include an opening (hereinafter referred to as the seventh opening, 230OP) corresponding to the hole region PH. The transmittance of the hole region PH may be improved (e.g., increased) by the seventh opening 230OP. A size (or width or diameter) of the seventh opening 230OP of the second electrode 230 may be smaller than the size (or width or diameter) of the third opening 123OP3.

The blocking metal layer BML includes an opening (hereinafter referred to as a ninth opening, BML-OP) overlapping the hole region PH, but a size (e.g., width or diameter) of the ninth opening BML_OP may be larger than the size (e.g., width or diameter) of the third opening 123OP3.

According to some embodiments, a spacing between the first conductive layers ML1 and a spacing between the second conductive layers ML2 of the touch screen layer 400 may be different from the spacing between the first conductive layers ML1 and the spacing between the second conductive layers ML2 in the first display area DA1 so that an area corresponding to the hole area PH in the touch screen layer 400 is defined. For example, the spacing between the first conductive layers ML1 and the spacing between the second conductive layers ML2 of the touch screen layer 400 in the second display area DA2 may be narrower than the spacing between the first conductive layers ML1 and the spacing between the second conductive layers ML2 in the first display area DA1.

Because the pixel circuit, wiring, pixel definition layer 123 of a transparent material, and light blocking layer 610 are not provided in the area corresponding to the hole area PH of the display panel, the transmittance of the second display area DA2 may be improved (e.g., increased) while maintaining the resolution of the second display area DA2 to be the same as the resolution of the first display area DA1.

FIGS. 8 to 10 schematically illustrate plan views of the second display area according to some embodiments of the present disclosure.

Referring to FIG. 8, a first data line 521 extending in a second direction (e.g., the y direction or −y direction) may be arranged on the second display area DA2. On the second display area DA2, a second data line 522 extending in a second direction (e.g., the y direction or the −y direction) and spaced apart from the first data line 521 in the first direction (e.g., the x direction or the −x direction) may be arranged. A first driving voltage line 511 may extend in a second direction (e.g., the y direction or the −y direction) and may be arranged adjacent to the first data line 521, and a second driving voltage line 512 may extend in a second direction (e.g., the y direction or the −y direction) and may be arranged adjacent to the second data line 522. The first driving voltage line 511 and the second driving voltage line 512 may be arranged spaced apart from each other in the first direction (e.g., the x direction or the −x direction).

The area between the first data line 521 and the second data line 522 may include a wiring area BS and a sensor area SS. The sensor area SS may be an area where a component 40 (see, e.g., FIG. 3A) is placed on the lower portion of the substrate 100 (see, e.g., FIG. 3A). The sensor region SS may be the hole region PH described in FIGS. 4 and 5. The sensor area SS may overlap with the opening 123OP3 (see, e.g., FIG. 7) of the pixel definition layer 123 (see, e.g., FIG. 7) and the opening 610OP3 (see, e.g., FIG. 7) of the light blocking layer 610 (see, e.g., FIG. 7). The component 40 may be a light sensor or an infrared sensor. However, the present invention is not limited thereto.

A distance d1 by which the first data line 521 and the second data line 522 adjacent to the sensor area SS are spaced apart in the first direction (e.g., the x direction or the −x direction) may be longer than a distance d2 by which the first data line 521 and the second data line 522 adjacent to the wiring area BS are spaced apart in the first direction (e.g., the x direction or the −x direction). The first data line 521 and the second data line 522 are arranged to be further apart from other areas in the sensor area SS, so that components arranged in the sensor area SS may be more efficient in obtaining data using light, etc.

According to some embodiments, a third data line 523 may be placed in the wiring area BS between the first data line 521 and the second data line 522. The third data line 523 may include a first portion 523a protruding from the first data line 521 in the first direction (e.g., the x direction) and a second portion 523b connected to the first portion 523a and extending in the second direction (e.g., the y direction or −y direction). In other words, the third data line 523 may not be placed in the sensor area SS. The sensor area SS may be an area where the third data line 523 is not placed.

According to some embodiments, a fourth data line 524 may be positioned between the first data line 521 and the second data line 522. The fourth data line 524 may include a third portion 524a protruding in the first direction (e.g., the x direction) and a fourth portion 524b connected to the third portion 524a and extending in the second direction (e.g., the y direction or −y direction). The fourth data line 524 is placed in the wiring area BS and may not be placed in the sensor area SS. In other words, the sensor area SS may be an area where the fourth data line 524 is not arranged. For example, the sensor area SS may be an area where the third data line 523 and the fourth data line 524 are not arranged.

In the first display area DA1, a plurality of wires extending in the second direction (e.g., the y direction or the −y direction) may be arranged between the first data line 521 and the second data line 522 extending in the second direction (e.g., the y direction or the −y direction). The second display area DA2 may be an area between the first data line 521 and the second data line 522 and may include the sensor area SS with components arranged below it. Therefore, unlike the first display area DA1, in the second display area DA2, multiple wires may not be arranged in the entire area between the first data line 521 and the second data line 522. In such examples, unlike the first display area DA1, a plurality of wires are not arranged between the first data line 521 and the second data line 522 in the second display area DA2, so a degree of flatness of the organic insulating layer of the first display area DA1 and a degree of flatness of the organic insulating layer of the second display area DA2 are different 1 from each other, and thus a difference in brightness or color may occur between the first display area DA1 and the second display area DA2. In addition, unlike the first display area DA1, in the second display area DA2, a plurality of wires are not arranged between the first data line 521 and the second data line 522, so that a capacitance of a parasitic capacitor occurring in the first display area DA1 and a capacitance of a parasitic capacitor occurring in the second display area DA2 are different from each other, and thus a luminance difference or color difference may occur between the first display area DA1 and the second display area DA2.

According to some embodiments of the present invention, the third data line 523 extended from the first data line 521 and the fourth data line 524 extended from the second data line 522 are arranged in the wiring area BS other than the sensor area SS among the areas between the first data line 521 and the second data line 522, so that a difference in the degree of flatness of an organic insulating layer between the first display area DA1 and the second display area DA2 may be reduced, and a difference in the capacitance of the parasitic capacitor occurring in the first display area DA1 and the second display area DA2 may also be reduced, so that the luminance difference or color difference between the first display area DA1 and the second display area DA2 may be prevented or substantially reduced, and the quality and reliability of the display device may be improved (e.g., increased).

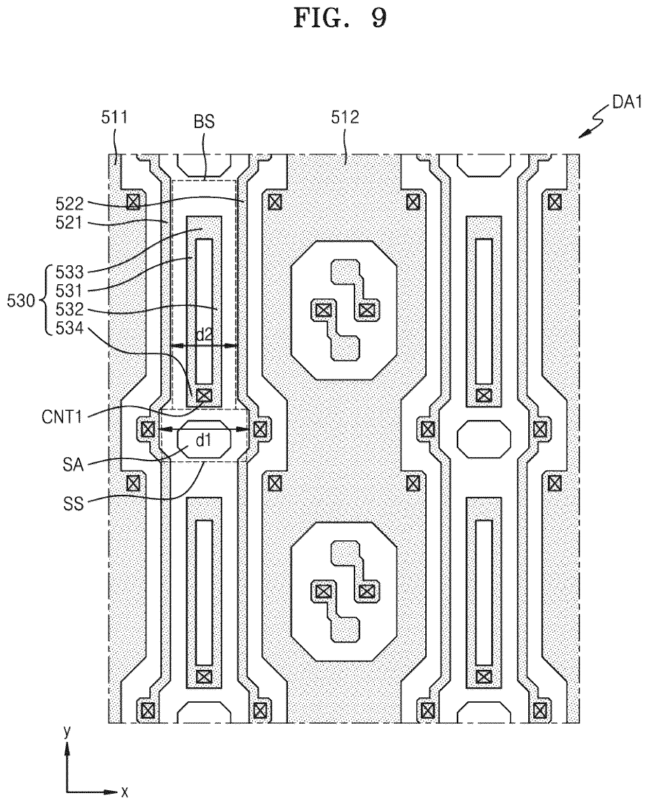

Referring to FIG. 9, according to some embodiments, a common voltage line 530 may be placed in an area between the first data line 521 and the second data line 522. A common voltage line 530 may be placed in the wiring area BA between the first data line 521 and the second data line 522. The common voltage line 530 may not be placed in the sensor area SS. In other words, the sensor area SS may be an area where the common voltage line 530 is not arranged. The common voltage line 530 is placed at the top and can be electrically connected to the counter electrode of the organic light-emitting element to which a common voltage ELVSS is applied through a contact hole CNT1.

The common voltage line 530 may include a first common voltage line 531 and a second common voltage line 532 that extend in the second direction (e.g., the y direction or the −y direction) and are arranged spaced apart from each other in the first direction (e.g., the x direction or the −x direction), and a third common voltage line 533 and a fourth common voltage line 534 that extend in the first direction (e.g., the x direction or the −x direction) and are arranged spaced apart from each other in the second direction (e.g., the y direction or the −y direction). The first common voltage line 531, the second common voltage line 532, the third common voltage line 533, and the fourth common voltage line 534 may be connected to each other. The first common voltage line 531, the second common voltage line 532, the third common voltage line 533, and the fourth common voltage line 534 may be provided in a rectangular shape. In other words, the common voltage line 530 may be provided in a square shape.

According to some embodiments of the present invention, the common voltage line 530 is arranged in the wiring area BA among the areas between the first data line 521 and the second data line 522 located in the second display area DA2, so that little to no difference in the degree of flatness of the organic insulating layer may occur between the first display area DA1 and the second display area DA2, and no difference in the capacitance of the parasitic capacitor occurring in the first display area DA1 and the second display area DA2 may occur, so that the luminance difference or the color difference may be prevented or substantially reduced between the first display area DA1 and the second display area DA2. In addition, by improving the voltage drop phenomenon of the common voltage ELVSS in the second display area DA2, the common voltage ELVSS applied to the pixel circuits PC of the second display area DA2 can be improved, and the quality and reliability of the display device may be improved (e.g., increased).

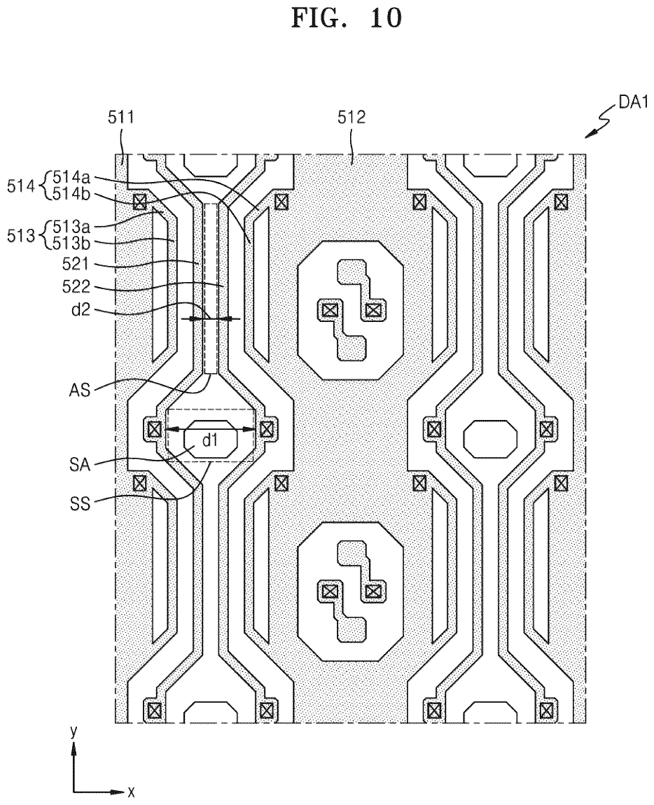

Referring to FIG. 10, the area between the first data line 521 and the second data line 522 may include a general area BS and the sensor area SS. The distance d1 along the first direction (e.g., along the x direction or the −x direction) between the first 1 data line 521 and the second data line 522 adjacent to the sensor area SS may be longer than the distance d2 along the first direction (e.g., along the x direction or the −x direction) between the first data line 521 and the second data line 522 adjacent to the general area BS.

A third driving voltage line 513 may include a fifth portion 513a protruding from the first driving voltage line 511 in a first direction (e.g., the x direction) and a sixth portion 513b connected to the fifth portion 513a and extending in the second direction (e.g., the y direction or −y direction). The third driving voltage line 513 may be placed apart from the sensor area SS. In other words, the sensor area SS may be an area where the third driving voltage line 513 is not arranged.

A fourth driving voltage line 514 may include a seventh portion 514a protruding from the second driving voltage line 512 in the first direction (e.g., the x direction) and an eighth portion 514b connected to the seventh portion 514a and extending in the second direction (e.g., the y direction or −y direction). The fourth driving voltage line 514 may be placed apart from the sensor area SS. In other words, the sensor area SS may be an area where the fourth driving voltage line 514 is not arranged.

According to some embodiments of the present invention, the third driving voltage line 513 extended from the first driving voltage line 511 and the fourth driving voltage line 514 extended from the second driving voltage line 512 are arranged in the second display area DA2, so that little to no difference in the degree of flatness of an organic insulating layer may occur between the first display area DA1 and the second display area DA2, and little to no difference in the capacitance of the parasitic capacitor occurring in the first display area DA1 and the second display area DA2 may occur, so that the luminance difference or the color difference may be prevented or substantially reduced between the first display area DA1 and the second display area DA2.

In addition, in addition to the first driving voltage line 511 and the second driving voltage line 512, the third driving voltage line 513 and the fourth driving voltage line 514 are further arranged so that a resistance of the driving voltage ELVDD in the first display area DA1 may be reduced, and a quality and reliability of the display device may be improved (e.g., increased). According to some embodiments, wires to which data Data, the common voltage ELVSS, or the driving voltage ELVDD is applied are arranged so as to be spaced apart from a sensor area arranged in the second display area DA2, so that little to no difference in the degree of flatness of the organic insulating layer may occur between the first display area DA1 and the second display area DA2, and no difference in the capacitance of the parasitic capacitor occurring in the first display area DA1 and the second display area DA2 may occur, so that the quality and reliability of the display device may be improved (e.g., increased).

According to some embodiments of the present invention as described above, the display device with improved reliability and quality may be implemented.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a first display area and a second display area comprising a sensor area;
a first data line arranged in the second display area and extending in a first direction;
a second data line arranged in the second display area, extending in the first direction, and arranged apart from the first data line in a second direction crossing the first direction; and
a third data line arranged between the first data line and the second data line, and comprising a first portion protruding from the first data line in the second direction and a second portion connected to the first portion and extending in the first direction,
wherein an area between the first data line and the second data line comprises a wiring area and the sensor area, and
wherein the third data line is arranged in the wiring area.

2. The display device of claim 1, wherein the sensor area overlaps an opening in a pixel definition layer and an opening in a light blocking layer.

3. The display device of claim 1, further comprising:
a fourth data line arranged between the first data line and the second data line and comprising a third portion protruding in the second direction from the second data line and a fourth portion connected to the third portion and extending in the first direction.

4. The display device of claim 1, wherein the fourth data line is arranged in the wiring area.

5. The display device of claim 1, wherein a distance by which the first data line adjacent to the sensor area and the second data line are arranged apart in the second direction is longer than a distance by which the first data line adjacent to the wiring area and the second data line are arranged apart in the second direction.

6. The display device of claim 3, wherein the third data line and the fourth data line are not in the sensor area.

7. The display device of claim 1, wherein a component is on a lower part of the substrate in the sensor area.

8. The display device of claim 7, wherein the component is a light sensor.

9. The display device of claim 7, wherein the component is an infrared sensor.

10. A display device comprising:
a substrate comprising a first display area and a second display area comprising a sensor area;
a first data line arranged in the second display area and extending in a first direction;
a second data line arranged in the second display area, extending in the first direction, and arranged apart in a second direction crossing the first direction; and
a common voltage line arranged between the first data line and the second data line,
wherein an area between the first data line and the second data line comprises a wiring area and the sensor area, and
wherein the common voltage line is arranged in the wiring area.

11. The display device of claim 10, wherein the common voltage line comprises a first common voltage line and a second common voltage line extending in the first direction and arranged spaced apart in the second direction, and a third common voltage line and a fourth common voltage line extending in the second direction and arranged apart in the first direction.

12. The display device of claim 11, wherein the first common voltage line, the second common voltage line, the third common voltage line, and the fourth common voltage line are connected to each other.

13. The display device of claim 12, wherein the first common voltage line, the second common voltage line, the third common voltage line, and the fourth common voltage line each have a rectangular shape.

14. The display device of claim 10, wherein the common voltage line is electrically connected to a counter electrode of an organic light-emitting diode on the common voltage line to which a common voltage is applied through a contact hole.

15. A display device comprising:
a substrate comprising a first display area and a second display area comprising a sensor area;
a first driving voltage line arranged in the second display area and extending in a first direction;
a second driving voltage line arranged apart from the first driving voltage line in a second direction crossing the first direction and extending in the first direction;
a first data line arranged between the first driving voltage line and the second driving voltage line and extending in the first direction;
a second data line arranged between the first data line and the second driving voltage line and extending in the first direction; and
a third driving voltage line comprising a fifth portion protruding in the second direction from the first driving voltage line and a sixth portion connected to the fifth portion and extending in the first direction,
wherein an area between the first data line and the second data line comprises a general area and the sensor area, and
wherein a distance by which the first data line adjacent to the sensor area and the second data line are arranged apart in the second direction is longer than a distance by which the first data line adjacent to the general area and the second data line are arranged apart in the second direction.

16. The display device of claim 15, wherein the third driving voltage line is arranged apart from the sensor area.

17. The display device of claim 15, further comprising:
a fourth driving voltage line comprising a seventh portion protruding in the second direction from the second driving voltage line and an eighth portion connected to the seventh portion and extending in the first direction.

18. The display device of claim 17, wherein the fourth driving voltage line is arranged apart from the sensor area.

19. The display device of claim 17, wherein the third driving voltage line and the fourth driving voltage line are not arranged in the sensor area.

20. An electronic device comprising:
a processor configured to provide input image data; and
a display device configured to display an image based on the input image data, the display device comprising:
a substrate comprising a first display area and a second display area comprising a sensor area;
a first data line arranged in the second display area and extending in a first direction;
a second data line arranged in the second display area, extending in the first direction, and arranged apart from the first data line in a second direction crossing the first direction; and
a third data line arranged between the first data line and the second data line, and comprising a first portion protruding from the first data line in the second direction and a second portion connected to the first portion and extending in the first direction,
wherein an area between the first data line and the second data line comprises a wiring area and the sensor area, and
wherein the third data line is arranged in the wiring area.
